(19) United States
(12) Patent Application Publication
(10) Pub. No.: US 2009/0067555 A1
(43) Pub. Date: Mar. 12, 2009

(54) FILTER CIRCUIT, RECEIVER USING THE SAME AND FILTERING METHOD

(76) Inventors: Masahiro HOSOYA, Kawasaki-shi (JP); Toshiya Mitomo, Kawagoe-shi (JP); Hidenori Okuni, Kawasaki-shi (JP); Hiroaki Ishihara, Fuchu-shi (JP); Osamu Watanabe, Chigasaki-shi (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 12/203,745

(22) Filed: Sep. 3, 2008

(30) Foreign Application Priority Data
Sep. 4, 2007 (JP) 2007-229325

(51) Int. Cl. H04L 27/06; H03M 1/00; H03M 3/00

(52) U.S. Cl. 375/344; 341/110; 341/143

(57) ABSTRACT

A filter circuit includes a sampler which samples an input signal to generate a first analog signal, an analog-to-digital converter which converts the first analog signal into a first digital signal, a digital filter which extracts a signal component out of a desired band from the first digital signal to generate a second digital signal, a digital-to-analog converter which converts the second digital signal into a second analog signal, a delay device which imparts a signal delay to the first analog signal to supply a third analog signal, the signal delay being equal to a delay time of the second analog signal relative to the first analog signal, and a subtracter which subtracts the second analog signal from the third analog signal to generate an output signal.

### CROSS-REFERENCE TO RELATED APPLICATIONS

This application is based upon and claims the benefit of priority from prior Japanese Patent Application No. 2007-229325, filed Sep. 4, 2007, the entire contents of which are incorporated herein by reference.

### BACKGROUND OF THE INVENTION

1. Field of the Invention

The present invention relates to a filter circuit which removes interference from a received signal, a receiver in which the filter circuit is used and a filtering method.

2. Description of the Related Art

In a receiver of a wireless communication system, a low-noise amplifier (LNA) amplifies a received signal obtained from an antenna receiving a wireless signal, and a frequency converter performs downconversion to generate a received baseband signal. A signal having a desired band is extracted from the received baseband signal through, for example, a low-pass filter (LPF), and an analog-to-digital converter (ADC) converts the signal into a digital received signal. At this point, sometimes a filter circuit is provided in front of the ADC to remove the interference.

As used herein, the interference shall mean unnecessary signals except for the signal having the desired band. Examples of the interference include a wireless signal sent from a transmitter or a transmitter and receiver main body which is different from a transmitter of a reception target and unnecessary transmission from another IC.

A filter circuit described in Danijela et al, “Novel Radio Architectures for UWB, 60 GHz, and Cognitive Wireless Systems,” EURASIP Journal on Wireless Communications and Networking, Vol. 2006, Article ID 17957, pp. 1-18 (related art) includes a first automatic gain control circuit, an ADC, a notch filter, an adaptive filter, a digital-to-analog converter (DAC), an analog delay element, a subtracter, and a second automatic gain control circuit. The filter circuit distributes an input signal into a first pathway formed by the first automatic gain control circuit, the ADC, the notch filter, the adaptive filter, and the DAC and a second pathway formed by the analog delay element.

The first automatic gain control circuit controls a signal amplitude of the input signal passing through the first pathway, and the ADC converts the input signal into a digital signal. The notch filter and the adaptive filter extract interference component from the digital signal, and the DAC converts the interference component into an analog signal. In the second pathway, the analog delay element imparts a signal delay corresponding to a delay time of the first pathway to the input signal.

Both the signals from the first and second pathways are fed into the subtracter, which removes the interference component by subtracting the signal having passed through the first pathway from the signal having passed through the second pathway. The second automatic gain control circuit adjusts a signal amplitude of the signal from which the interference component has been removed, and supplies the signal to a subsequent-stage ADC.

In the first pathway of the filter circuit described in the related art, digital signal processing, that is, discrete-time signal processing is performed to correctly determine the delay time based on a clock. On the other hand, in the second pathway, it is necessary that the analog delay element impart the signal delay equal to the delay time to the input signal. However, the delay time imparted to the input signal by the analog delay element is not constant because the delay time depends on a frequency of the input signal, and the delay time is changed by temperature and process conditions.

Therefore, it is difficult that the delay time imparted in the first pathway is exactly matched with the delay time imparted in the second pathway. The subtracter cannot correctly remove the interference component unless the delay times imparted in both the pathways are matched with each other. Additionally, tuning is separately required in order to compensate the change in delay time caused by the temperature and process conditions.

### BRIEF SUMMARY OF THE INVENTION

According to an aspect of the invention, there is provided a filter circuit comprising: a sampler which samples an input signal to generate a first analog signal; an analog-to-digital converter which converts the first analog signal into a first digital signal; a digital filter which extracts a signal component out of a desired band from the first digital signal to generate a second digital signal; a digital-to-analog converter which converts the second digital signal into a second analog signal; a delay device which imparts a signal delay to the first analog signal to supply a third analog signal, the signal delay being equal to a delay time of the second analog signal relative to the first analog signal; and a subtracter which subtracts the second analog signal from the third analog signal to generate an output signal.

According to another aspect of the invention, there is provided a filter circuit comprising: a sampler which samples an input signal to generate a first analog signal; an analog-to-digital converter which converts the first analog signal into a first digital signal; a digital filter which extracts a signal component out of a desired band from the first digital signal to generate a second digital signal; a ΔΣ modulator which performs ΔΣ modulation to the second digital signal to obtain a third digital signal; a digital-to-analog converter which converts the third digital signal into a second analog signal; a delay device which imparts a signal delay to the first analog signal to supply a third analog signal, the signal delay being equal to a delay time of the second analog signal relative to the first analog signal; a subtracter which subtracts the second analog signal from the third analog signal to generate a fourth analog signal; and a filter which removes a quantization noise from the fourth analog signal to generate an output signal, the quantization noise being generated by the ΔΣ modulator.

According to another aspect of the invention, there is provided a filter circuit comprising: a sampler which samples an input signal to generate a first analog signal; a first analog-to-digital converter which converts the first analog signal into a first digital signal; a digital filter which extracts a signal component out of a desired band from the first digital signal to generate a second digital signal; a digital-to-analog converter which converts a third digital signal into a second analog signal, the third digital signal being formed by higher-level bits of the second digital signal; a first delay device which imparts a first signal delay to the first analog signal to supply a third analog signal, the first signal delay being equal to a first delay time of the second analog signal relative to the first analog signal; a first subtracter which subtracts the second analog signal from the third analog signal to generate a fourth analog signal; a second analog-to-digital converter which converts the fourth analog signal into a fourth digital signal; a second delay device which imparts a second signal delay to a fifth digital signal to supply a sixth digital signal, the second signal delay being equal to a second delay time of the fourth digital signal relative to the second digital signal, the fifth digital signal being formed by lower-level bits of the second digital signal; and a second subtracter which subtracts the sixth digital signal from the fourth digital signal to generate an output signal.

According to another aspect of the invention, there is provided a filter circuit comprising: a first sampler which samples an input signal to generate a first analog signal; an analog-to-digital converter which has a second sampler and converts a second analog signal into a first digital signal; a digital filter which extracts a signal component out of a desired band from the first digital signal to generate a second digital signal; a digital-to-analog converter which converts the second digital signal into a third analog signal; a delay device which imparts a signal delay to the first analog signal to supply a fourth analog signal, the signal delay being equal to a delay time of the third analog signal relative to the second analog signal; and a subtracter which subtracts the third analog signal from the fourth analog signal to generate an output signal.

According to another aspect of the invention, there is provided a filter circuit comprising: a sampler which samples an input signal to generate a first analog signal; a filter which extracts a low-frequency component from the first analog signal to obtain a second analog signal; a decimeter which performs downsampling of the second analog signal to obtain a third analog signal; an analog-to-digital converter which converts the third analog signal into a first digital signal; a digital filter which extracts a signal component out of a desired band from the first digital signal to generate a second digital signal; a digital-to-analog converter which converts the second digital signal into a fourth analog signal; a delay device which imparts a signal delay to the third analog signal to supply a fifth analog signal, the signal delay being equal to a delay time of the fourth analog signal relative to the third analog signal; and a subtracter which subtracts the fourth analog signal from the fifth analog signal to generate an output signal.

### BRIEF DESCRIPTION OF THE SEVERAL VIEWS OF THE DRAWING

FIG. 1 is a block diagram showing a filter circuit according to a first embodiment and surroundings thereof;

FIG. 2 is a circuit diagram showing an example of a sampler of FIG. 1;

FIG. 3A is a circuit diagram showing an example of a DAC of FIG. 1;

FIG. 3B is a graph showing an operation of a switch of FIG. 3A;

FIG. 4A is a circuit diagram showing an example of a delay device of FIG. 1;

FIG. 4B is a graph showing an operation of a switch of FIG. 4A;

FIG. 5 is a block diagram showing a filter circuit according to a second embodiment and surroundings thereof;

FIG. 6 is a block diagram showing a filter circuit according to a third embodiment and surroundings thereof;

FIG. 7 is a block diagram showing a filter circuit according to a fourth embodiment and surroundings thereof;

FIG. 8 is a block diagram showing a filter circuit according to a fifth embodiment and surroundings thereof;

FIG. 9A is a circuit diagram showing an example of a filter and a decimeter of FIG. 8;

FIG. 9B is a graph showing an operation of a switch of FIG. 9A; and

FIG. 10 is a block diagram showing a receiver according to a sixth embodiment of the invention.

### DETAILED DESCRIPTION OF THE INVENTION

Embodiments of the invention will be described below with reference to the accompanying drawings.

### First Embodiment

As shown in FIG. 1, a filter circuit 100 according to a first embodiment of the invention is inserted between a frequency converter 10 and an analog-to-digital converter (ADC) 20, and includes a sampler 110, an ADC 121, a digital filter 122, a digital-to-analog converter (DAC) 130, a delay device 140, and a subtracter 150.

The frequency converter 10 generates a received baseband signal by performing downconversion of a received signal received by an antenna (not shown). It is assumed that the baseband signal includes a desired wave and interference component having an amplitude larger than that of the desired wave. The filter circuit 100 of the first embodiment removes the interference component. The ADC 20 converts the signal from the filter circuit 100 into a digital signal, and a digital processing unit (not shown) demodulates the digital signal.

The sampler 110 samples the received baseband signal from the frequency converter 10 at a predetermined sampling frequency to make the signal temporally discrete. The analog discrete-time signal from the sampler 110 is branched into a first pathway formed by the ADC 121, the digital filter 122, and the DAC 130 and a second pathway formed by the delay device 140.

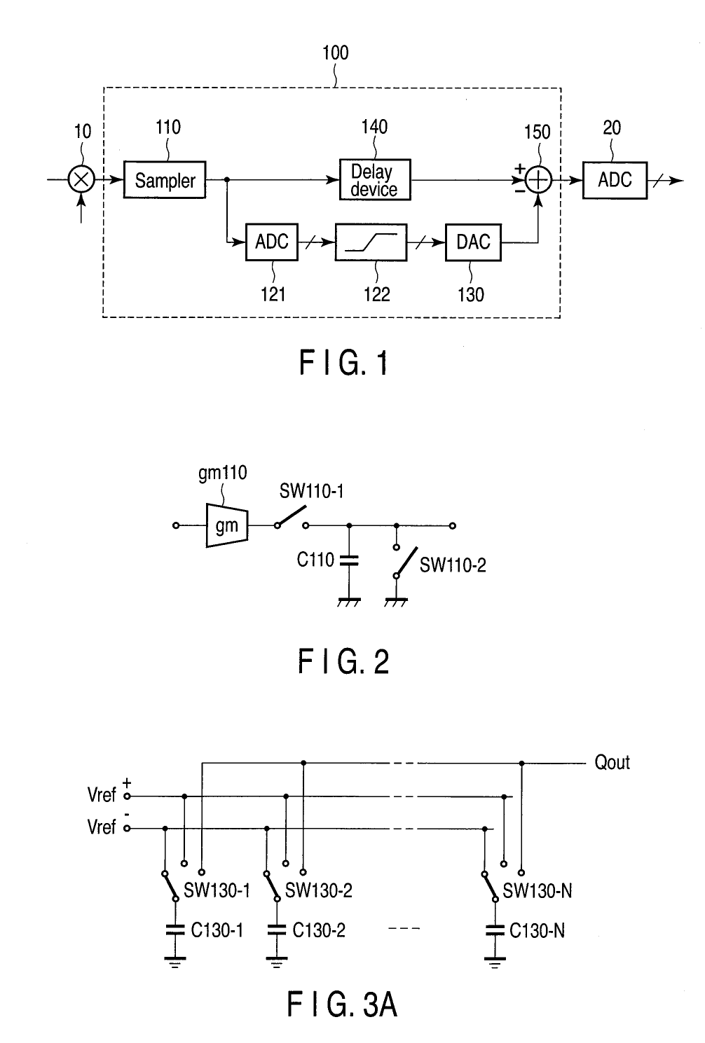

A charge sampler which is an example of the sampler 110 will be described with reference to FIG. 2. The charge sampler shown in FIG. 2 includes a transconductance amplifier gm₁₁₀ which converts an input voltage into a current, a capacitor C₁₁₀ which performs charge sampling to an output current of the transconductance amplifier gm₁₁₀, a switch SW₁₁₀₋₁ which controls the charge sampling, and a switch SW₁₁₀₋₂ which resets a charge of capacitor C₁₁₀.

The two switches SW₁₁₀₋₁ and SW₁₁₀₋₂ are operated in a complementary manner, and one of the switches S_{W110-1} and SW₁₁₀₋₂ is turned on while the other is turned off. Capacitor C₁₁₀ performs the charge sampling to the output current of the transconductance amplifier gm₁₁₀ when switch SW₁₁₀₋₁ is turned on, and the charge of capacitor C₁₁₀ is reset when switch SW₁₁₀₋₂ is turned on. The sampler 110 is not limited to the charge sampler of FIG. 2. For example, a voltage sampler may be used as the sampler 110.

The ADC 121 converts the analog discrete-time signal from the sampler 110 into the digital signal, and inputs the digital signal to the digital filter 122.

The digital filter 122 extracts the interference component except for the desired band in the digital signal from the ADC 121, and generates a digital signal including the interference component. The DAC 130 converts the interference component, which is included in the digital signal generated by the digital filter 122, into an analog discrete-time signal.

The digital filter 122 and the DAC 130 generate a quantization noise in the frequency band of the desired wave. Desirably bit resolution (quantization bit rate) of each of the digital filter 122 and the DAC 130 is determined by a signal-to-noise ratio (SNR) necessary for the system. Specifically, because a dynamic range of about 6 dB corresponds to one bit, at least one bit is required per 6 dB of sum of a ratio of the input signal in the desired band to the input signal out of the desired band and the signal-to-noise ratio in the desired band.

In a usual wireless signal processing apparatus, the bit resolution of the DAC 130 is higher than the bit resolution of the ADC 121. Generally, the DAC and the ADC have the same bit resolution, and the DAC can be designed in a low power consumption manner rather than the ADC.

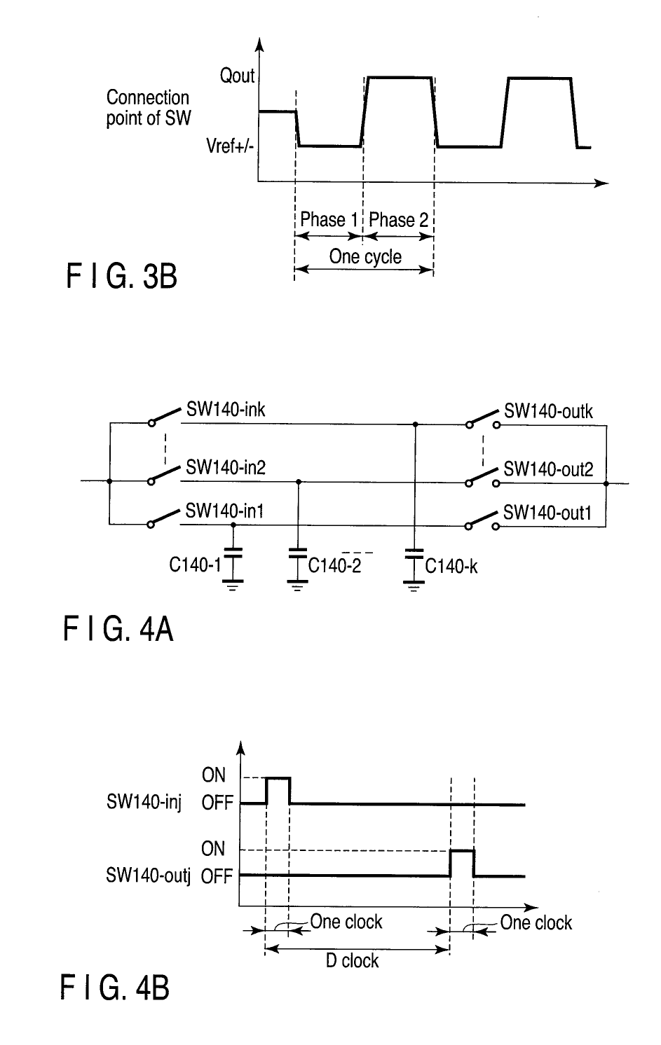

An example of the DAC 130 will be described with reference to FIGS. 3A and 3B. The DAC shown in FIG. 3A having bit resolution N includes N capacitors C₁₃₀₋₁ to C_{130-N} and switches SW₁₃₀₋₁ to SW_{130-N} which switch connections of the capacitors. Capacitors C₁₃₀₋₁ to C_{130-N} correspond to bits of the digital signal fed into the DAC. That is, capacitor C₁₃₀₋₁ corresponds to the least significant bit (LSB), and capacitor C_{130-N} corresponds to the most significant bit (MSB). A capacitance of each of capacitors C₁₃₀₋₁ to C_{130-N} is weighed by a binary weight, the capacitance of capacitor C₁₃₀₋₂ becomes double the capacitance of capacitor C₁₃₀₋₁, and the capacitance of capacitor C_{130-N} becomes 2^{N-1} times the capacitance of capacitor C₁₃₀₋₁.

As shown in FIG. 3B, switches SW₁₃₀₋₁ to SW_{130-N} repeat a switch operation in which one cycle includes two phases. In a phase 1, each of switches SW₁₃₀₋₁ to SW_{130-N} is connected such that a reference voltage Vref+ or Vref− is applied to capacitors C₁₃₀₋₁ to C_{130-N}. In the phase 1, which of the reference voltage Vref+ or Vref− is applied to each of capacitors C₁₃₀₋₁ to C_{130-N} is determined based on whether the digital filter 122 supplies a high or low level for the bit corresponding to the capacitor. In the phase 1, the charge is accumulated in each of capacitors C₁₃₀₋₁ to C_{130-N} according to the digital input. On the other hand, in a phase 2, switches SW₁₃₀₋₁ to SW_{130-N} connect capacitors C₁₃₀₋₁ to C_{130-N} to an output Qout of the DAC, and the charges accumulated in capacitors C₁₃₀₋₁ to C_{130-N} are superposed and supplied as an analog discrete-time signal.

In the filter circuit according to the first embodiment, in order to correctly remove the interference, it is necessary that a gain from the first pathway be matched with a gain from the second pathway in the interference frequency. In order to match the gains from the both pathways with each other, using the DAC of FIG. 3A as the DAC 130, it is only necessary to adjust the reference voltages Vref+ and Vref− to control amplitude of the supplied analog discrete-time signal to a proper value.

The delay device 140 imparts a signal delay to the analog discrete-time signal supplied from the sampler 110. The signal delay is equal to the delay time generated in the first pathway, that is, the ADC 121, the digital filter 122, and the DAC 130. The delay time generated in the first pathway is obtained as a discrete value in which a clock period is multiplied by a constant because clock control is performed to the ADC 121, the digital filter 122, and the DAC 130. Accordingly, the delay device 140 can determine the delay time using a simple digital circuit such as a counter which counts the number of clocks.

An example of the delay device 140 will be described with reference to FIGS. 4A and 4B. The delay device shown in FIG. 4A is formed by arranging K unit circuits in parallel (K is an integer more than one). The unit circuit is formed by two switches SWᵢₙ and SWₒᵤₜ and a capacitor C provided between switches SWᵢₙ and SWₒᵤₜ. The delay device of FIG. 4A can generate signal delays of clocks ranging from “1” to “K−1”.

The input signal is connected to one of capacitors C₁₄₀₋₁ to C₁₄₀₋ₖ by K switches SW₁₄₀₋ᵢₙ₁ to SW₁₄₀₋ᵢₙₖ, and an input charge is accumulated. That is, switches SW₁₄₀₋ᵢₙ₁ to SW₁₄₀₋ᵢₙₖ are exclusively operated, and one of switches SW₁₄₀₋ᵢₙ₁ to SW₁₄₀₋ᵢₙₖ is turned on while all the other switches are tuned off. It is assumed that charges are not accumulated in capacitors C₁₄₀₋₁ to C₁₄₀₋ₖ in the initial state. Then, similarly the input charge is sequentially accumulated in the empty capacitor.

Similarly switches SW₁₄₀₋ₒᵤₜ₁ to SW₁₄₀₋ₒᵤₜₖ are exclusively operated, and supply the input charges accumulated in the corresponding capacitors when a predetermined delay time elapses. For example, FIG. 4B shows operations of switches SW₁₄₀₋ᵢₙⱼ and SW₁₄₀₋ₒᵤₜⱼ in the case where the delay time is set at D clock (D is an integer smaller than K, and j is an integer of 1 to K). The input charge is accumulated in capacitor C₁₄₀₋ᵢₙⱼ through switch SW₁₄₀₋ᵢₙⱼ. Similarly, the input charge is sequentially accumulated in the empty capacitor until the (D−1) clock elapses, and the input charge is taken out from capacitor C₁₄₀₋ⱼ through switch SW₁₄₀₋ₒᵤₜⱼ when the D clock elapses. Then, the charge accumulated in capacitor C₁₄₀₋ⱼ is reset to zero. Similarly, the input charges are sequentially taken out from other capacitors in the order in which the input charge is accumulated, and the accumulated charges are reset to zero. At this point, the input charge fed into the delay device is also accumulated in one of the (N−D) empty capacitors.

The subtracter 150 subtracts the analog discrete-time signal having passed through the second pathway from the analog discrete-time signal having passed through the first pathway, and feeds the subtraction result into the ADC 20. At this point, although the analog discrete-time signal having passed through the first pathway includes both the desired wave and the interference, the analog discrete-time signal having passed through the second pathway mainly includes only the interference, so that the interference component can be removed by the subtraction of the analog discrete-time signal having passed through the second pathway from the analog discrete-time signal having passed through the first pathway.

In order to demodulate an original signal from the signal component in the desired band of the baseband signal, it is necessary that the desired signal amplitude corresponding to several bits be ensured in the ADC. In the wireless communication system, generally the interference whose signal amplitude is larger than that of the desired wave by tens of decibel exists in a frequency band near the desired band. Accordingly, a higher bit resolution is required because the input amplitude of the ADC is saturated simply by ensuring the desired signal amplitude. Specifically, assuming that L dB is a ratio of voltage amplitudes of the desired wave and interference, at least L/6 bit is required in addition to the bit resolution for ensuring the desired signal amplitude.

It is known that current consumption of the ADC is increased in proportion to the bit resolution N to the power of two. In the filter circuit 100 of the first embodiment, the ADC 121 is provided to realize the ADC having the equivalently high bit resolution. The bit resolution necessary for the subsequent-stage ADC 20 can be decreased only by the bit resolution of the ADC 121, so that the current consumption of the subsequent-stage ADC 20 can be reduced.

The filter circuit 100 according to the first embodiment will be described in comparison with the conventional technique.

In the conventional technique, it is necessary to perform the processing of the analog continuous-time signal because the sampler is not used, and the analog delay element is used as the delay device. Accordingly, as described above, because the variation in delay time is generated by the signal frequency and the temperature and process conditions, it is difficult to correctly generate the signal delay.

On the other hand, in the filter circuit 100 according to the first embodiment, because the sampler 110 is used, the delay device 140 retains the discrete-time analog signal for the predetermined number of clocks to supply the discrete-time analog signal, which allows the signal delay to be correctly generated. Accordingly, the signal delay generated in the first pathway is matched with the signal delay generated in the second pathway, and the subtracter 150 can accurately remove the interference component. Because the delay time is determined by the number of clocks, it is only necessary to adjust the delay time during design. In the filter circuit 100 according to the first embodiment, the accuracy of interference cancel is enhanced, so that the bit resolution of the subsequent-stage ADC can substantially be improved.

### Second Embodiment

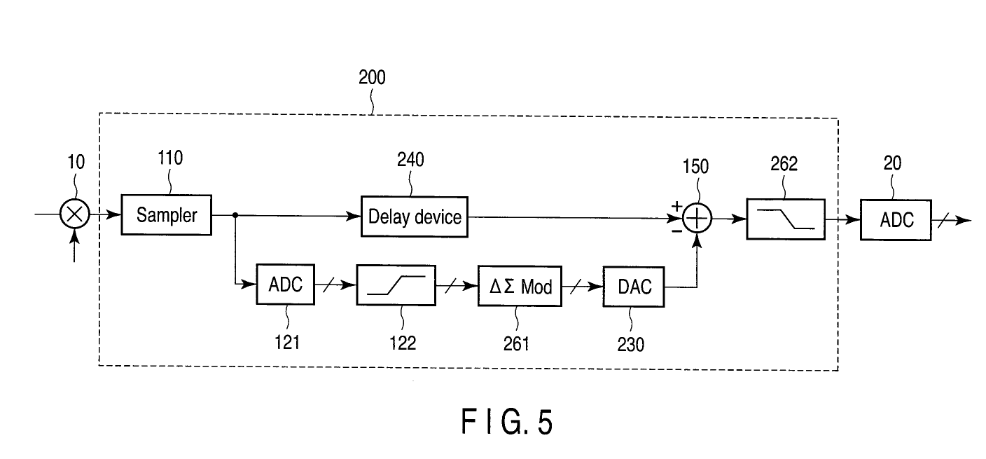

As shown in FIG. 5, a filter circuit 200 according to a second embodiment of the invention is inserted between the frequency converter 10 and the ADC 20, and includes the sampler 110, the ADC 121, the digital filter 122, a ΔΣ modulator 261, a DAC 230, a delay device 240, the subtracter 150, and a filter 262. In FIG. 5, the same components as those in the first embodiment of FIG. 1 are designated by the same numerals, and the different component will be mainly described.

The ΔΣ modulator 261 performs ΔΣ modulation to the digital signal generated by the digital filter 122, and supplies the modulated digital signal to the DAC 230. Because the ΔΣ modulator 261 performs feedback of a low-frequency signal such that an error is decreased, the quantization noise of the digital signal is removed toward a high-frequency side by a noise shaping effect after the ΔΣ modulation.

The DAC 230 converts the digital signal from the ΔΣ modulator 261 into the analog signal. At this point, the bit resolution of the DAC 230 is determined by the signal-to-noise ratio necessary for the desired band. However, because the noise shaping of the quantization noise is generated by the ΔΣ modulator 261, the signal-to-noise ratio is suppressed to a lower level in the desired band. Accordingly, the DAC 230 can be formed with the bit resolution lower than that of the DAC 130 of FIG. 1.

The delay device 240 imparts the signal delay to the analog discrete-time signal supplied from the sampler 110. The signal delay is equal to the delay time generated in the ADC 121, the digital filter 122, the ΔΣ modulator 261, and the DAC 230.

The filter 262 which is a moving average filter removes the high-frequency component of the analog discrete-time signal supplied from the subtracter 150. That is, in the filter circuit 200 according to the second embodiment, because the noise shaping of the quantization noise is generated by the ΔΣ modulator 261, the quantization noise is increased near a Nyquist frequency of the subsequent-stage ADC 20. Accordingly, the filter 262 removes the quantization noise component removed to the high-frequency region by the ΔΣ modulator 261, thereby preventing the saturation of the input amplitude of the ADC 20.

Thus, in the filter circuit according to the second embodiment, the ΔΣ modulator is provided in front of the DAC to perform the noise shaping of the quantization noise. Accordingly, in the filter circuit according to the second embodiment, the bit resolution of the DAC can be reduced because the signal-to-noise ratio can be improved in the desired band. Additionally, the input amplitude of the ADC is not saturated, because the quantization noise to which the noise shaping is performed is removed by the filter before fed into the subsequent-stage ADC.

### Third Embodiment

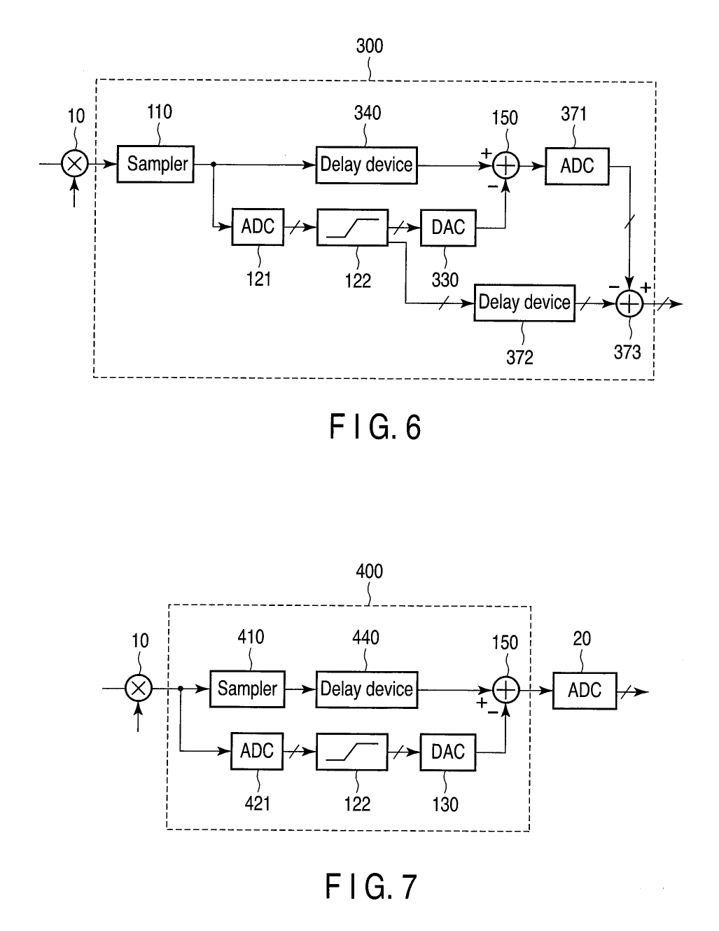

As shown in FIG. 6, a filter circuit 300 according to a third embodiment of the invention is provided subsequent to the frequency converter 10, and includes the sampler 110, the ADC 121, the digital filter 122, a DAC 330, a delay device 340, the subtracter 150, an ADC 371, a delay device 372, and a subtracter 373. In FIG. 6, the same components as those in the first embodiment of FIG. 1 are designated by the same numerals, and the different component will be mainly described.

The DAC 330 receives only a high-level bit in the digital signal generated by the digital filter 122, and converts the high-level bit of the digital signal to generate the analog discrete-time signal. The remaining lower-level bits of the digital signal generated by the digital filter 122 are fed into the delay device 372. At this point, how much bit resolution in the digital signal generated by the digital filter 122 is allocated to the higher-level bit is not particularly limited. For example, it is determined based on the bit resolution of the DAC 330. The DAC 330 has accuracy higher than the bit resolution.

The delay device 340 imparts the signal delay to the analog discrete-time signal supplied from the sampler 110. The signal delay is equal to the delay time generated in the ADC 121, the digital filter 122, and the DAC 330.

The subtracter 150 performs the subtraction processing to the analog discrete-time signals supplied from the DAC 330 and the delay device 340, and the subtraction result is fed into the ADC 371. The ADC 371 has the bit resolution higher than that of the DAC 330, and converts the discrete-time analog signal from the subtracter 150 into the digital signal corresponding to the bit resolution. Because the bit resolution of the DAC 330 is lower than the bit resolution of the digital filter 122, the large quantization noise is generated in the frequency band of the desired wave of the digital signal supplied from the ADC 371, thereby deteriorating the signal-to-noise ratio.

As described above, in the digital signal generated by the digital filter 122, only the lower-level bit is fed into the delay device 372. The delay device 372 imparts the signal delay to the digital signal. The signal delay is equal to the delay time generated in the DAC 330, the subtracter 150, and the ADC 371.

The subtracter 373 subtracts the digital signal supplied from the delay device 372 from the digital signal supplied from the ADC 371. The digital signal supplied from the delay device 372 is the lower-level bit of the digital signal supplied from the digital filter 122, and the amplitude and phase of the digital signal supplied from the delay device 372 are close to those of the quantization noise generated in the DAC 330. Accordingly, the quantization noise is removed by the subtraction processing, and the signal-to-noise ratio of the desired wave can be improved.

Thus, in the filter circuit according to the third embodiment, the output of the digital filter is branched into the higher-level bit and the lower-level bit, the subtraction is performed to the higher-level bit in the analog domain like the first embodiment, and the subtraction is performed to the lower-level bit in the digital domain, thereby removing the interference component. Accordingly, in the filter circuit according to the third embodiment, the interference component removing performance similar to that of the first embodiment can be obtained while the bit resolution of the DAC which receives the output of the digital filter is restrained.

### Fourth Embodiment

As shown in FIG. 7, a filter circuit 400 according to a fourth embodiment of the invention is inserted between the frequency converter 10 and the ADC 20, and includes a sampler 410, an ADC 421, the digital filter 122, the DAC 130, a delay device 440, and the subtracter 150. In FIG. 7, the same components as those in the first embodiment of FIG. 1 are designated by the same numerals, and the different component will be mainly described.

The ADC 421 includes a sampler, which can convert the input analog continuous-time signal into the analog discrete-time signal. Accordingly, in the filter circuit 400 according to the fourth embodiment, it is not necessary to provide the sampler in front of the ADC 421.

The sampler 410 is operated in synchronization with the clock like the sampler in the ADC 421, and converts the received baseband signal from the frequency converter 10 into the analog discrete-time signal.

The delay device 440 imparts the signal delay to the analog discrete-time signal supplied from the sampler 410. The signal delay is equal to the delay time generated in the ADC 421, the digital filter 122, and the DAC 130.

Thus, the ADC including the sampler is used in the filter circuit according to the fourth embodiment. Accordingly, in the filter circuit according to the fourth embodiment, it is not necessary that the sampler be shared between the first pathway and the second pathway.

### Fifth Embodiment

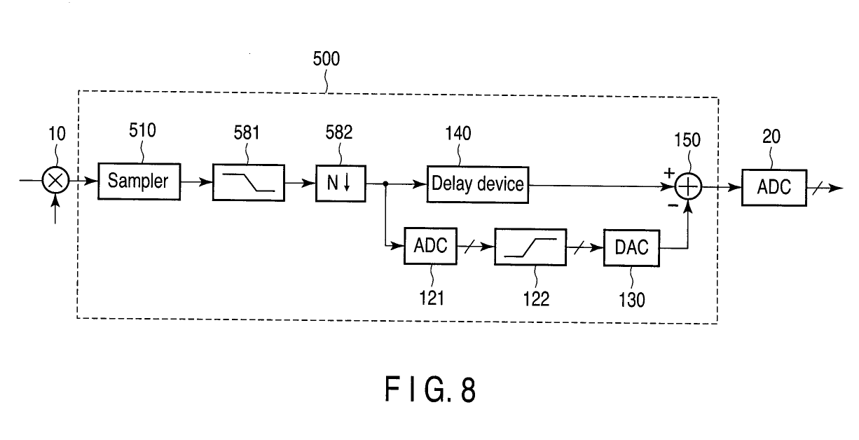

As shown in FIG. 8, a filter circuit 500 according to a fifth embodiment of the invention is inserted between the frequency converter 10 and the ADC 20, and includes a sampler 510, a filter 581, a decimeter 582, the ADC 121, the digital filter 122, the DAC 130, the delay device 140, and the subtracter 150. In FIG. 8, the same components as those in the first embodiment of FIG. 1 are designated by the same numerals, and the different component will be mainly described.

The sampler 510 has the sampling frequency higher than that of the sampler 110. The sampler 510 samples the received baseband signal supplied from the frequency converter 10, and converts the received baseband signal into the analog discrete-time signal.

As described above, the sampler 510 has the relatively higher sampling frequency, and the sampling is performed at a high speed. Therefore, the decimeter 582 performs downsampling to the analog discrete-time signal supplied from the sampler 510 before the analog discrete-time signal is fed into the ADC 121.

In order to restrain folding which is generated by the downsampling performed by the decimeter 582, the filter 581 which is a moving average filter removes the frequency component, at which the folding is generated in the desired band after the downsampling, from the analog discrete-time signal supplied from the sampler 510.

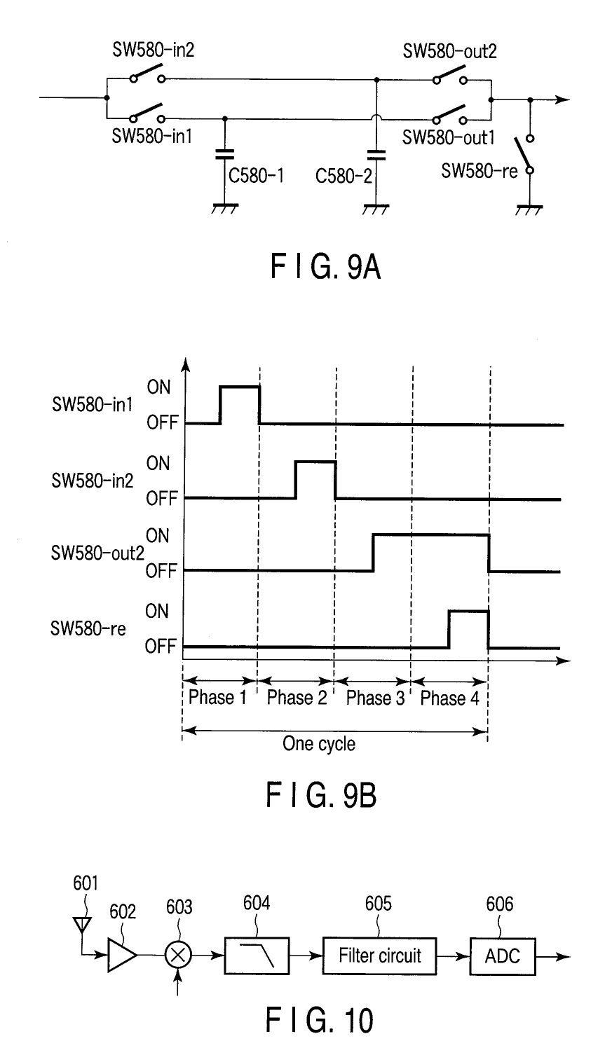

The decimeter 582 performs the downsampling to the analog discrete-time signal having passed through the filter 581, and inputs the analog discrete-time signal to the ADC 121. The filter 581 and the decimeter 582 may be combined. For example, the filter 581 and the decimeter 582 can be realized by a circuit shown in FIG. 9A.

The circuit shown in FIG. 9A includes switches SW₅₈₀₋ᵢₙ₁, SW₅₈₀₋ᵢₙ₂, SW₅₈₀₋ₒᵤₜ₁, SW₅₈₀₋ₒᵤₜ₂, and SW₅₈₀₋ᵣₑ and capacitors C₅₈₀₋₁ and C₅₈₀₋₂, and performs the downsampling to the fed analog discrete-time signal at a decimation rate of ½. The circuit shown in FIG. 9A performs the downsampling with one cycle including four phases as shown in FIG. 9B.

In a phase 1, switch SW₅₈₀₋ᵢₙ₁ is turned on to accumulate the input signal charge in capacitor C₅₈₀₋₁, and then switch SW₅₈₀₋ᵢₙ₁ is turned off to hold the charge accumulated in capacitor C₅₈₀₋₁. In a phase 2, switch SW₅₈₀₋ᵢₙ₂ is turned on to accumulate the input signal charge in capacitor CG₅₈₋₂, and then switch SW₅₈₀₋ᵢₙ₂ is turned off to hold the charge accumulated in capacitor CG₅₈₀₋₂. In a phase 3, both switches SW₅₈₀₋ₒᵤₜ₁ and SW₅₈₀₋ₒᵤₜ₂ are turned on to accumulate the input signal charges in capacitors C₅₈₀₋₁ and C₅₈₀₋₂, and the charges accumulated in capacitors C₅₈₀₋₁ and C₅₈₀₋₂ are superposed and supplied. In a phase 4, switch SW₅₈₀₋ᵣₑ is turned on to reset the charges accumulated in capacitors C₅₈₀₋₁ and C₅₈₀₋₂ to zero, and switches SW₅₈₀₋ₒᵤₜ₁, SW₅₈₀₋ₒᵤₜ₂, and SW₅₈₀₋ᵣₑ are turned off. In the circuit shown in FIG. 9A, the four phases are repeated to perform the downsampling to the input analog discrete-time signal.

Thus, in the filter circuit according to the fifth embodiment, the filter and the decimeter are provided in the subsequent stage of the sampler to perform the downsampling to the analog discrete-time signal generated by the sampler. Accordingly, in the filter circuit according to the fifth embodiment, the sampler having the higher sampling frequency can be used, and the interference having the frequency not lower than the Nyquist frequency of the ADC which receives the analog discrete-time signal from the sampler can be removed.

Although only one set of the filter 581 and decimeter 582 is provided in the filter circuit 500 shown in FIG. 5, two or more sets of the filters 581 and decimeters 582 may be provided. The sampler 510 may directly perform the sampling to the RF signal without providing the frequency converter 10.

### Sixth Embodiment

As shown in FIG. 10, a receiver according to a sixth embodiment of the invention includes an antenna 601, a low noise amplifier 602, a frequency converter 603, a filter 604, a filter circuit 605, and an analog-to-digital converter 606.

The low noise amplifier 602 amplifies the received signal received by the antenna 601, and the frequency converter 603 performs the downconversion of the received signal. The filter 604 is a low-pass filter which removes the high-frequency interference component included in the received baseband signal generated by the frequency converter 603.

The filter circuit 605 is the filter circuit according to one of the first to fifth embodiments, and further removes the interference component from the received baseband signal in which the high-frequency interference component is removed by the filter 604. The analog-to-digital converter 606 converts the output signal of the filter circuit 605 into the digital signal, and a digital signal processing unit (not shown) demodulates the digital signal.

Thus, in the sixth embodiment, the filter circuit according to one of the first to fifth embodiments is provided between the low-pass filter and the analog-to-digital converter. Accordingly, in the receiver according to the sixth embodiment, the accuracy of interference component removal is improved, and the power consumption is reduced because the analog-to-digital converter can be used at a lower bit resolution.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A filter circuit comprising:
a sampler which samples an input signal to generate a first analog signal;
an analog-to-digital converter which converts the first analog signal into a first digital signal;
a digital filter which extracts a signal component out of a desired band from the first digital signal to generate a second digital signal;
a digital-to-analog converter which converts the second digital signal into a second analog signal;
a delay device which imparts a signal delay to the first analog signal to supply a third analog signal, the signal delay being equal to a delay time of the second analog signal relative to the first analog signal; and
a subtracter which subtracts the second analog signal from the third analog signal to generate an output signal.

2. The circuit according to claim 1, wherein the analog-to-digital converter has resolution of at least one bit per six decibel of attenuation of the output signal relative to the input signal out of the desired band.

3. The circuit according to claim 1, wherein the digital filter and the digital-to-analog converter have resolution of at least one bit per six decibel of a sum of a ratio of the input signal in the desired band to the input signal out of the desired band and a signal-to-noise ratio of the output signal in the desired band.

4. The circuit according to claim 1, wherein the delay device temporarily accumulates the first analog signal, and supplies the first analog signal as the third analog signal when the delay time elapses.

5. A filter circuit comprising:
a sampler which samples an input signal to generate a first analog signal;
an analog-to-digital converter which converts the first analog signal into a first digital signal;
a digital filter which extracts a signal component out of a desired band from the first digital signal to generate a second digital signal;
a ΔΣ modulator which performs ΔΣ modulation to the second digital signal to obtain a third digital signal;
a digital-to-analog converter which converts the third digital signal into a second analog signal;
a delay device which imparts a signal delay to the first analog signal to supply a third analog signal, the signal delay being equal to a delay time of the second analog signal relative to the first analog signal;
a subtracter which subtracts the second analog signal from the third analog signal to generate a fourth analog signal; and
a filter which removes a quantization noise from the fourth analog signal to generate an output signal, the quantization noise being generated by the digital-to-analog converter.

6. The circuit according to claim 5, wherein the analog-to-digital converter has resolution of at least one bit per six decibel of attenuation of the output signal relative to the input signal out of the desired band.

7. The circuit according to claim 5, wherein the digital filter and the digital-to-analog converter have resolution of at least one bit per six decibel of a sum of a ratio of the input signal in the desired band to the input signal out of the desired band and a signal-to-noise ratio of the output signal in the desired band.

8. The circuit according to claim 5, wherein the delay device temporarily accumulates the first analog signal, and supplies the first analog signal as the third analog signal when the delay time elapses.

9. A filter circuit comprising:
a sampler which samples an input signal to generate a first analog signal;
a first analog-to-digital converter which converts the first analog signal into a first digital signal;
a digital filter which extracts a signal component out of a desired band from the first digital signal to generate a second digital signal;
a digital-to-analog converter which converts a third digital signal into a second analog signal, the third digital signal being formed by higher-level bits of the second digital signal;
a first delay device which imparts a first signal delay to the first analog signal to supply a third analog signal, the first signal delay being equal to a first delay time of the second analog signal relative to the first analog signal;
a first subtracter which subtracts the second analog signal from the third analog signal to generate a fourth analog signal;
a second analog-to-digital converter which converts the fourth analog signal into a fourth digital signal;
a second delay device which imparts a second signal delay to a fifth digital signal to supply a sixth digital signal, the second signal delay being equal to a second delay time of the fourth digital signal relative to the second digital signal, the fifth digital signal being formed by lower-level bits of the second digital signal; and
a second subtracter which subtracts the sixth digital signal from the fourth digital signal to generate an output signal.

10. The circuit according to claim 9, wherein the first analog-to-digital converter has resolution of at least one bit per six decibel of attenuation of the output signal relative to the input signal out of the desired band.

11. The circuit according to claim 9, wherein the digital filter has resolution of at least one bit per six decibel of a sum of a ratio of the input signal in the desired band to the input signal out of the desired band and a signal-to-noise ratio of the output signal in the desired band.

12. The circuit according to claim 9, wherein the first delay device temporarily accumulates the first analog signal, and supplies the first analog signal as the third analog signal when the first delay time elapses.

13. A filter circuit comprising:
a first sampler which samples an input signal to generate a first analog signal;
an analog-to-digital converter which has a second sampler and converts a second analog signal into a first digital signal, the second sampler sampling the input signal to generate the second analog signal;
a digital filter which extracts a signal component out of a desired band from the first digital signal to generate a second digital signal;
a digital-to-analog converter which converts the second digital signal into a third analog signal;
a delay device which imparts a signal delay to the first analog signal to supply a fourth analog signal, the signal delay being equal to a delay time of the third analog signal relative to the second analog signal; and
a subtracter which subtracts the third analog signal from the fourth analog signal to generate an output signal.

14. The circuit according to claim 13, wherein the analog-to-digital converter has resolution of at least one bit per six decibel of attenuation of the output signal relative to the input signal out of the desired band.

15. The circuit according to claim 13, wherein the digital filter and the digital-to-analog converter have resolution of at least one bit per six decibel of a sum of a ratio of the input signal in the desired band to the input signal out of the desired band and a signal-to-noise ratio of the output signal in the desired band.

16. The circuit according to claim 13, wherein the delay device temporarily accumulates the first analog signal, and supplies the first analog signal as the forth analog signal when the delay time elapses.

17. A filter circuit comprising:
a sampler which samples an input signal to generate a first analog signal;
a filter which extracts a low-frequency component from the first analog signal to obtain a second analog signal;
a decimeter which performs downsampling of the second analog signal to obtain a third analog signal;
an analog-to-digital converter which converts the third analog signal into a first digital signal;
a digital filter which extracts a signal component out of a desired band from the first digital signal to generate a second digital signal;
a digital-to-analog converter which converts the second digital signal into a fourth analog signal;
a delay device which imparts a signal delay to the third analog signal to supply a fifth analog signal, the signal delay being equal to a delay time of the fourth analog signal relative to the third analog signal; and
a subtracter which subtracts the fourth analog signal from the fifth analog signal to generate an output signal.

18. A receiver comprising:
a low noise amplifier which amplifies a received wireless signal to obtain an amplified signal;
a frequency converter which performs downconversion of the amplified signal to generate a baseband signal;
the filter circuit according to claim 1 which receives the baseband signal as the input signal to obtain a filtering signal as the output signal;
an analog-to-digital converter which converts the filtering signal into a digital signal; and
a demodulator which demodulates the digital signal.

19. A filtering method comprising:
sampling an input signal to generate a first analog signal;
converting the first analog signal into a first digital signal;
extracting a signal component out of a desired band from the first digital signal to generate a second digital signal;
converting the second digital signal into a second analog signal;
imparting a signal delay to the first analog signal to supply a third analog signal, the signal delay being equal to a delay time of the second analog signal relative to the first analog signal; and
subtracting the second analog signal from the third analog signal to generate an output signal.
